(19) United States
(12) Patent Application Publication
(10) Pub. No.: US 2026/0160833 A1
(43) Pub. Date: Jun. 11, 2026

(54) SMART AUXILIARY CONTACT-BASED CONTACTOR STATE DETECTION SYSTEM

(71) Applicant: LG ENERGY SOLUTION, LTD., Seoul (KR)

(72) Inventors: Sagar Nagaluru, Rochester Hills, MI (US); Mohammad Rupok, Sterling Heights, MI (US); Sandeep Vankineni, Northville, MI (US); Bhavya Jampani, Warren, MI (US)

(73) Assignee: LG ENERGY SOLUTION, LTD., Seoul (KR)

(21) Appl. No.: 18/974,141

(22) Filed: Dec. 9, 2024

(51) Int. Cl. G01R 31/66

(52) U.S. Cl. CPC G01R 31/66

(57) ABSTRACT

A battery system for monitoring a state of a battery subpack may be provided. The battery system may include a battery unit, a positive contactor having a primary positive contactor electrically connected to a positive terminal of the battery unit, and an auxiliary positive contactor including a common (COM) pin, a normally-closed (NC) pin, and a normally-open (NO) pin, a negative contactor electrically connected to a negative terminal of the battery unit, a microprocessor configured to control the positive and negative contactors, a COM control circuit configured to provide an electrical signal to the COM pin, an NC sensing circuit configured to monitor an electrical signal from the NC pin, and an NO sensing circuit configured to monitor an electrical signal from the NO pin. The microprocessor may determine a state of the battery system based on information about the electrical signals from the NC pin and the NO pin.

### TECHNICAL FIELD

Various embodiments of the present disclosure relate generally to methods and systems for monitoring/detecting an abnormal state of a battery system and, more particularly, for monitoring/detecting an abnormal state of a contactor of a battery system.

### BACKGROUND

Batteries are increasingly being integrated into a wide range of mobile devices, including smartphones, laptops, electric vehicles (EVs), hybrid electric vehicles (HEVs), plug-in hybrid electric vehicles (PHEVs), and energy storage systems (ESS). To ensure optimal performance and safety, these batteries are often paired with a Battery Management System (BMS) that oversees their overall operation.

The batteries in mobile devices undergo frequent charging and discharging cycles, often utilizing a contactor to connect or disconnect the batteries from external devices, such as loads or chargers. Repeated operation can cause the contactor to experience fatigue, leading to welding of the contacts in either an open or closed position. This fatigue can be caused by the inrush and/or cutoff currents generated during its operations. A welded contactor may fail to respond to control signals, potentially allowing high currents to discharge from the high-voltage battery and cause significant damage to connected loads. Therefore, accurate monitoring of contactor states is crucial for ensuring safety and efficient operation in high-voltage systems, such as electric vehicle battery systems.

Conventional methods for detecting contactor states often rely on complex circuitry and sensors, which can be both expensive and prone to failure. Moreover, the reliance on intricate systems may pose maintenance challenges and compromise the overall performance of the battery system.

### SUMMARY OF THE DISCLOSURE

According to certain aspects of the disclosure, methods and systems are disclosed for monitoring/detecting an abnormal state of a battery system, more particularly, for monitoring/detecting an abnormal state of a contactor of a battery system.

For instance, a battery system may include a battery unit; a positive contactor having: a primary positive contactor electrically connected to a positive terminal of the battery unit; and an auxiliary positive contactor comprising a common (COM) pin, a normally-closed (NC) pin, and a normally-open (NO) pin, wherein the COM pin is configured to be electrically connected to the NC pin when the primary positive contactor is in an open state, and the COM pin is configured to be electrically connected to the NO pin when the primary positive contactor is in a closed state; a negative contactor electrically connected to a negative terminal of the battery unit; a microprocessor configured to control the positive contactor and the negative contactor; a COM control circuit configured to provide an electrical signal to the COM pin; an NC sensing circuit configured to monitor an electrical signal from the NC pin and transmit first information about the electrical signal from the NC pin to the microprocessor; an NO sensing circuit configured to monitor an electrical signal from the NO pin and transmit second information about the electrical signal from the NO pin to the microprocessor, wherein the microprocessor is configured to determine whether the battery system is in an abnormal state based on the first information about the electrical signal from the NC pin and the second information about the electrical signal from the NO pin.

A battery system may include one or more battery subpacks, each of the one or more battery subpacks comprising: a battery unit; a positive contactor having: a primary positive contactor electrically connected to a positive terminal of the battery unit; and an auxiliary positive contactor comprising a common (COM) pin, a normally-closed (NC) pin, and a normally-open (NO) pin, wherein the COM pin is configured to be electrically connected to the NC pin when the primary positive contactor is in an open state, and the COM pin is configured to be electrically connected to the NO pin when the primary positive contactor is in a closed state; a negative contactor being electrically connected to a negative terminal of the battery unit; a subpack microprocessor configured to control the positive contactor and the negative contactor; a battery disconnect unit configured to open and close the primary positive contactor in response to a command from the subpack microprocessor to open or close the primary positive contactor; a COM control circuit configured to provide an electrical signal to the COM pin; an NC sensing circuit configured to monitor an electrical signal from the NC pin and transmit first information about the electrical signal from the NC pin to the subpack microprocessor; an NO sensing circuit configured to monitor an electrical signal from the NO pin and transmit second information about the electrical signal from the NO pin to the subpack microprocessor, wherein the subpack microprocessor of the one or more battery subpacks is configured to determine whether the corresponding battery subpack is in an abnormal state based on the first information about the electrical signal from the NC pin and the second information about the electrical signal from the NO pin.

A method of managing a battery system, wherein the battery system comprises a battery unit; a positive contactor having: a primary positive contactor electrically connected to a positive terminal of the battery unit; and an auxiliary positive contactor comprising a common (COM) pin, a normally-closed (NC) pin, and a normally-open (NO) pin, wherein the COM pin is configured to be electrically connected to the NC pin when the primary positive contactor is in an open state, and the COM pin is configured to be electrically connected to the NO pin when the primary positive contactor is in a closed state; a negative contactor electrically connected to a negative terminal of the battery unit; a microprocessor configured to control the positive contactor and the negative contactor; a COM control circuit configured to provide an electrical signal to the COM pin; an NC sensing circuit configured to monitor an electrical signal from the NC pin and transmit first information about the electrical signal from the NC pin to the microprocessor; an NO sensing circuit configured to monitor an electrical signal from the NO pin and transmit second information about the electrical signal from the NO pin to the microprocessor, wherein the method may include determining, by the microprocessor, whether the battery system is in an abnormal state based on the first information about the electrical signal from the NC pin and the second information about the electrical signal from the NO pin.

Additional objects and advantages of the disclosed embodiments will be set forth in part in the description that follows, and in part will be apparent from the description, or may be learned by practice of the disclosed embodiments.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 illustrates an exemplary block diagram of a system for monitoring/detecting an abnormal state of a battery system according to an example of the present disclosure.

FIG. 2A illustrates an exemplary auxiliary positive contactor of the system of FIG. 1 according to an example of the present disclosure.

FIG. 2B illustrates an exemplary battery disconnect unit of the system of FIG. 1 according to an example of the present disclosure.

FIGS. 3A-3F illustrate a flow diagram of example methods 300A-300F for monitoring/detecting an abnormal state of a battery system according to an example embodiment of the present disclosure.

FIG. 4 illustrates an example of a table having information about normal/abnormal operation conditions of the contactors according to an example embodiment of the present disclosure.

### DETAILED DESCRIPTION OF EMBODIMENTS

In general, the present disclosure is directed to methods and systems for monitoring/detecting an abnormal state of a battery system and, more particularly, for monitoring/detecting an abnormal state of a contactor of a battery system.

Aspects of the present disclosure may utilize auxiliary contacts (e.g., common pin, normally-closed pin, normally-open pin) for a contactor to detect the state of the contactor. These auxiliary contacts may be designed to provide a sense back signal, similarly to a loop, when voltage is applied to the auxiliary contacts. For example, by applying a low voltage to the auxiliary contacts and monitoring the state of these auxiliary contacts, for example, via sensing circuits, the system according to aspects of the present disclosure may be able to accurately determine whether the primary positive/negative contacts of the contactor are open or closed.

The system according to aspects of the present disclosure may provide a reliable sense back signal using auxiliary contacts and require minimal additional components and, thus, can be easily integrated into the existing battery systems. Therefore, aspects of the present disclosure may eliminate the need for complex circuitry and sensors, making it a cost-effective and reliable solution for contactor state detection.

In addition, while conventional methods utilizing complex circuitry and sensors often require significant time (e.g., 3-5 minutes) to identify abnormal conditions in a contactor, the system according to aspects of the present disclosure may monitor the state of the contactor continuously (e.g., every milliseconds) using the auxiliary contacts and monitoring circuits, thereby enabling more prompt diagnosis of abnormal conditions of a contactor. Aspects of the present disclosure can be applied in various high-voltage systems, where accurate contactor state detection is essential, such as electric vehicle batteries, renewable energy systems, and industrial equipment.

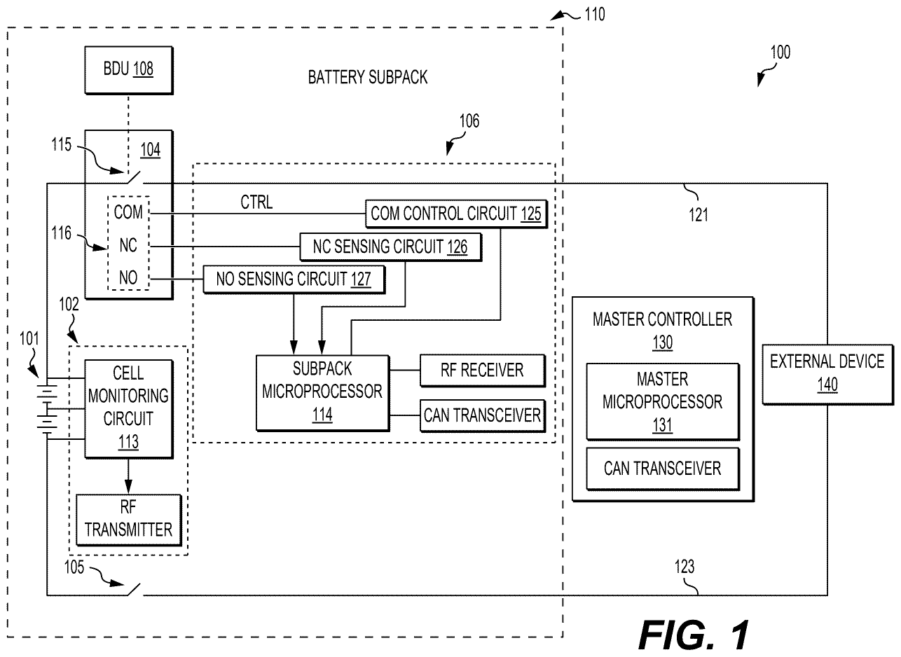

FIG. 1 depict an exemplary block diagram of a system 100 for monitoring/detecting an abnormal state of the system 100 (e.g., a battery subpack thereof). In some examples, the system 100 may be a Battery Management System (BMS) configured to monitor, manage, and/or protect battery packs. In some examples, the system 100 may be part of a mobile device, such as an electric vehicle, a hybrid electric vehicle, a plug-in hybrid electric vehicle, a smartphones, a laptop, and an energy storage system. In some examples, the system 100 may generally operate at a high voltage (e.g., 1,000-1,200 V).

As shown in FIG. 1, the system 100 may include one or more battery subpacks 110, a positive electrical connector 121, a negative electrical connector 123, and a master controller 130. Although there is one battery subpack shown in FIG. 1, the number of battery subpacks can be more than one (e.g., 2, 3, 4, 5, 6, 7, 8, 9, 10, . . . ). As shown in FIG. 1, in some examples, each of the one or more battery subpacks 110 may include a battery unit 101, a Cell Supervisory Circuit (CSC) 102, a positive contactor 104, a negative contactor 105, a Battery Electronic Control Module (BECM) 106, and a Battery Disconnect Unit (BDU) 108.

In some examples, each battery unit 101 of the one or more battery subpacks 110 may have a module design. For example, each battery unit 101 may be a battery module. In some examples, each battery module may include a plurality of battery submodules. In some examples, the number of the battery submodules in each of the battery modules may be in a range of about 8 to 64 submodules. For example, each of the battery modules 101 may include 8, 16, 32, or 64 submodules. In other examples, each of the battery modules may include any other suitable number of battery submodules.

In some examples, each of the battery submodules may include multiple battery cells. In some examples, the number of the battery cells in each of the battery submodules may be in a range of 2 to 64 battery cells. For example, each of the battery submodules may include 2, 4, 8, 16, 32, or 64 battery cells. In other examples, each of the battery submodules may include any other suitable number of battery cells.

In some other examples, each battery unit 101 may have a moduleless design. In this case, each battery unit 101 of the battery subpack 110 may comprise one or more battery cells within the battery subpack 110, for example, without a module package/housing therebetween. In some examples, the number of battery cells in each of the battery units 101 may be in a range of 2 to 4096 battery cells. For example, each of the battery units 101 may include 2, 4, 8, 16, 32, 64, 128, 256, 512, 1024, 2048, or 4096 battery cells. In other examples, each of the battery units 101 may include any other suitable number of battery cells.

In some examples, the CSC 102 may include a cell monitoring circuit 113 configured to detect the voltage and/or current value of the battery unit 101. In some examples, the cell monitoring circuit 113 may be configured to transmit information about the voltage and/or current value of the battery unit 101 to the BECM 106, for example, through a transmitter (e.g., RF transmitter).

In some examples, the positive contactor 104 may include a primary positive contactor 115 and an auxiliary positive contactor 116. In some examples, the primary positive contactor 115 may be a normally-open contactor that is normally open when the primary positive contactor 115 is not energized/activated (e.g., when not receiving any command to be closed and/or when the system 100 is turned off). The primary positive contactor 115 may be electrically connected to a positive terminal of the battery unit 101, and the negative contactor 105 may be electrically connected to the negative terminal of the battery unit 101.

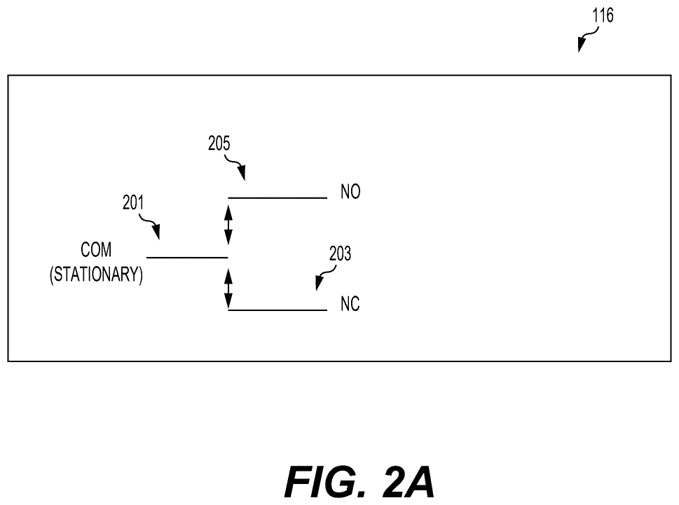

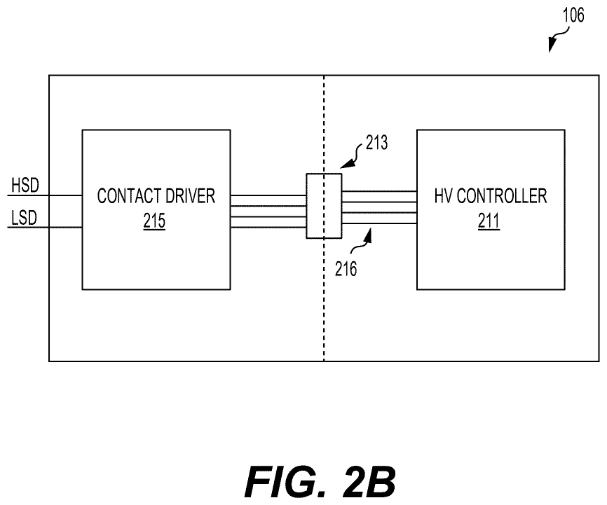

As shown in FIG. 2A, in some examples, the auxiliary positive contactor 116 may include a common (COM) pin 201, a normally-closed (NC) pin 203, and a normally-open (NO) pin 205. The NC pin 203 may be normally-closed (i.e., connected to the COM pin 201) and the NO pin 205 may be normally-open (i.e., not connected to the COM pin 201) when the auxiliary positive contactor 116 is not energized. As used herein, the term “pin” may refer to a node, terminal, and/or electrical connector that may serve as a path for an electrical signal.

The auxiliary positive contactor 116 may be energized/de-energized based on the state of the primary positive contactor 115. For example, the auxiliary positive contactor 116 may be de-energized when the primary positive contactor 115 is in an open state. The COM pin 201 may be electrically connected to the NC pin 203 when the auxiliary positive contactor 116 is de-energized. The auxiliary positive contactor 116 may be energized when the primary positive contactor 115 is in a closed state. The COM pin 201 may be electrically connected to the NO pin 205 when the auxiliary positive contactor 116 is energized.

In some examples, the COM pin 201 may be stationary, and the NC pin 203 and the NO pin 205 may move (e.g., in an upward/downward direction) to be connected to/disconnected from the COM pin 201. For example, when the primary positive contactor 115 is in an open state, the NC pin 203 may move (e.g., in an upward direction) to be connected to the COM pin 201. Similarly, when the primary positive contactor 115 is in a closed state, the NC pin 203 may move (e.g., in a downward direction) to be connected to the COM pin 201.

In some examples, the BECM 106 may include a subpack microprocessor 114, a COM control circuit 125, an NC sensing circuit 126, and an NO sensing circuit 127. In some examples, the subpack microprocessor 114 may be configured to open and close the primary positive contactor 115 and/or the negative contactor 105. In some examples, the subpack microprocessor 114 may transmit/receive data to/from the cell monitoring circuit 113 wirelessly as shown in FIG. 1 or via a wired connection. For example, the subpack microprocessor 114 may be configured to receive the information about the voltage and/or current value of the battery unit 101 from the cell monitoring circuit 113, for example, through a receiver (e.g., RF receiver).

In some examples, the COM control circuit 125 may be configured to provide an electrical signal to the COM pin 201. For example, the COM control circuit 125 may provide an electrical signal to the COM pin in response to a command from the subpack microprocessor 114. The electrical signal from the COM control circuit 125 may include a high logic level signal and a low logic level signal. In some examples, the high and low logic level signals may be 5.0 V (high) and 0.0 V (low) or 3.3 V (high) and 0.0 V (low). In other examples, the high and low logic level signals may be any other suitable electrical signals (e.g., any other suitable voltage values or digital signals, such as 1 (high) and 0 (low)).

In some examples, the COM control circuit 125 may be configured to transmit information about the electrical signal provided to the COM pin 201 to the subpack microprocessor 114. Based on the information from the COM control circuit 125, the subpack microprocessor 114 may be able to determine whether the electrical signal output from the COM control circuit 125 to the COM pin 201 is a high logic level signal or a logic level signal.

In some examples, the NC sensing circuit 126 may be configured to monitor/detect an electrical signal from the NC pin 203. For example, when the COM pin 201 is receiving a high logic level signal and the NC pin 203 is connected to the COM pin 201, the NC sensing circuit 126 may detect a high logic level signal from the NC pin 203. When the COM pin 201 is receiving a low logic level signal and the NC pin 203 is connected to the COM pin 201, the NC sensing circuit 126 may detect a low logic level signal from the NC pin 203. When the NC pin 203 is not connected to the COM pin 201, the NC sensing circuit 126 may detect a low logic level signal from the NC pin 203. The NC sensing circuit 126 may transmit information about the electrical signal from the NC pin 203 to the subpack microprocessor 112.

In some examples, the NO sensing circuit 127 may be configured to monitor/detect an electrical signal from the NO pin 205. For example, when the COM pin 201 is receiving a high logic level signal and the NO pin 205 is connected to the COM pin 201, the NO sensing circuit 127 may detect a high logic level signal from the NO pin 205. When the COM pin 201 is receiving a low logic level signal and the NO pin 205 is connected to the COM pin 201, the NO sensing circuit 127 may detect a low logic level signal from the NO pin 205. When the NO pin 205 is not connected to the COM pin 201, the NO sensing circuit 127 may detect a low logic level signal from the NO pin 205. The NO sensing circuit 127 may transmit information about the electrical signal from the NO pin 205 to the subpack microprocessor 112. In some examples, the COM control circuit 125, NC sensing circuit 126, and NO sensing circuit 127 may serve as a monitoring circuit that monitors the electrical signals of the COM pin 201, NC pin 203, and NO pin 205, respectively.

In some examples, the NC sensing circuit 126 may monitor the electrical signal from the NC pin 203 at a first predetermined time interval, and the NO sensing circuit 127 is configured to monitor the electrical signal from the NO pin 205 at a second predetermined time interval. In some examples, the first predetermined time interval and the second predetermined time interval may be in a range of about 50 milliseconds to about 200 milliseconds. In other examples, the first predetermined time interval and the second predetermined time interval may have any other suitable time interval.

In some examples, the CSC 102, BECM 106, and BDU 108 may be formed on a separate (circuit) board. For example, the components of the CSC 102 may be formed on a CSC board, the components of the BECM 106 may be formed on a BECM board separate from the CSC board, and/or the components of the BDU 108 may be formed on a BDU board separate from the CSC and BECM boards.

Referring to FIG. 2B, the BDU 108 may include a high voltage (HV) controller 211, an isolation barrier 213, a contact driver 215, and one or more communication lines 216 between the HV controller 211 and the contact driver 215. In some examples, the high voltage (HV) controller 211 may be operated in a high voltage domain (e.g., 1,000-1,200 V), and the contact driver 215 may be operated in a low voltage domain (e.g., 12 V). In some examples, the contact driver 215 may include a high side driver (HSD) circuit and a low side driver (LSD) circuit.

The subpack microprocessor 114 may open and close the primary positive contactor 115 and/or the negative contactor 105 through the BDU 108. For example, the subpack microprocessor 114 may receive, from an upper level controller (e.g., a controller of a mobile device), a command to open/close the primary positive contactor 115 and/or the negative contactor 105 and, responsive to receiving the command from the upper level controller, the subpack microprocessor 114 may transmit a command to open/close the primary positive contactor 115 and/or the negative contactor 105 to the HV controller 211. In some examples, the command to open/close the primary positive contactor 115 and/or the negative contactor 105 from the subpack microprocessor 114 may be transmitted to the HV controller 211 via a daisy chain communication interface/network or any other suitable communication interface/network.

In response to receiving the command, the HV controller 211 may transmit a control signal to the contact driver 215. For example, the HV controller 211 may transmit a control signal to the HSD and LSD circuits of the contact driver 215. The control signals from the HV controller 211 may pass the isolation barrier 213 and be transmitted to the contact driver 215 (e.g., HSD and LSD circuits) via the one or more communication lines 216. Examples of the one or more communication lines 216 may include a Serial Peripheral Interface (SPI). In response, the HSD and LSD circuits of the contact driver 215 may generate a signal to close the primary positive contactor 115 and/or the negative contactor 105. For example, the HSD and LSD circuits of the contact driver 215 may energize a contactor coil, which may move the primary positive contactor 115 and/or the negative contactor 105 to a closed position. In some examples, when the subpack microprocessor 114 stops transmitting a command to the HV controller 211, the contact driver 215 (e.g., the HSD and LSD circuits) may de-energize the contactor coil, which may move the primary positive contactor 115 and/or the negative contactor 105 to an open position. In this way, the high voltage command from the HV controller 211 may be converted into a low voltage command (e.g., from the contact driver 215, which may be operated in a low voltage domain (e.g., 12 V)).

In some examples, the master controller 130 may include a master microprocessor 131. The subpack microprocessor 114 may be configured to transmit the information about the voltage and/or current value of the battery unit 101 to the master microprocessor 131, for example, through a transmitter (e.g., CAN transmitter). The master microprocessor 131 may be configured to receive the information about the voltage and/or current value of the battery unit 101 from the subpack microprocessor 114, for example, through a receiver (e.g., CAN receiver). In some examples, the master microprocessor 131 may transmit/receive data to/from the subpack microprocessor 114 wirelessly as shown in FIG. 1 or via a wired connection. For example, the subpack microprocessor 114 may transmit information about the status of the battery subpack 110 (e.g., contactor welding, errors in sensing circuits or any other circuits of the battery subpack 110, etc.) to the master microprocessor 131, through a receiver (e.g., CAN receiver).

The master microprocessor 131 may be configured to control all or some components of the one or more battery subpacks 110, for example, by using the respective subpack microprocessor 114. For example, the master microprocessor 131 may be configured to open and close the primary positive contactor 115 and the negative contactor 105, for example, by transmitting opening/closing commands to the respective subpack microprocessor 114.

In some examples, when there are more than one battery subpack, the battery subpacks 110 may be connected to each other in parallel through the positive electrical connector 121 and the negative electrical connector 123. For example, the positive electrical connector 121 may be connected to the primary positive contactors of the battery subpacks 110, and the negative electrical connector 123 may be connected to the negative contactors of the battery subpacks 110.

In some examples, the system 100 may further include a main positive contactor, a precharge contactor, and a main negative contactor (now shown). The main positive contactor may be connected to the positive electrical connector 121, and the main negative contactor may be connected to the negative electrical connector 123. The main positive contactor and the main negative contactor may be configured to connect and/or disconnect the one or more battery subpacks 110 with and/or from an external device 140, for example, by closing/opening the main positive contactor and the main negative contactor. Examples of the external device may include a powertrain (of an electric vehicle), a battery charger (e.g., for charging the one or more battery subpacks 110) and a battery backup system (e.g., for providing power from the one or more battery subpacks 110 to houses, offices, stores, restaurants, or any other suitable facilities, for example, during power outages). In some examples, the master microprocessor 131 may be configured to control (e.g., open/close, etc.) the main positive contactor, precharge contactor, and main negative contactor, and/or any other components of the system 100.

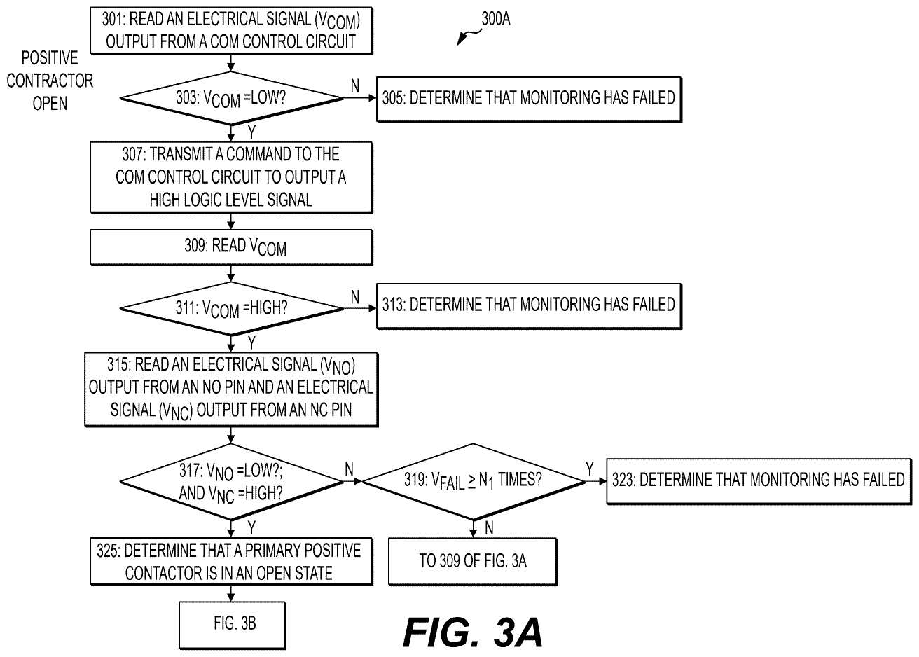

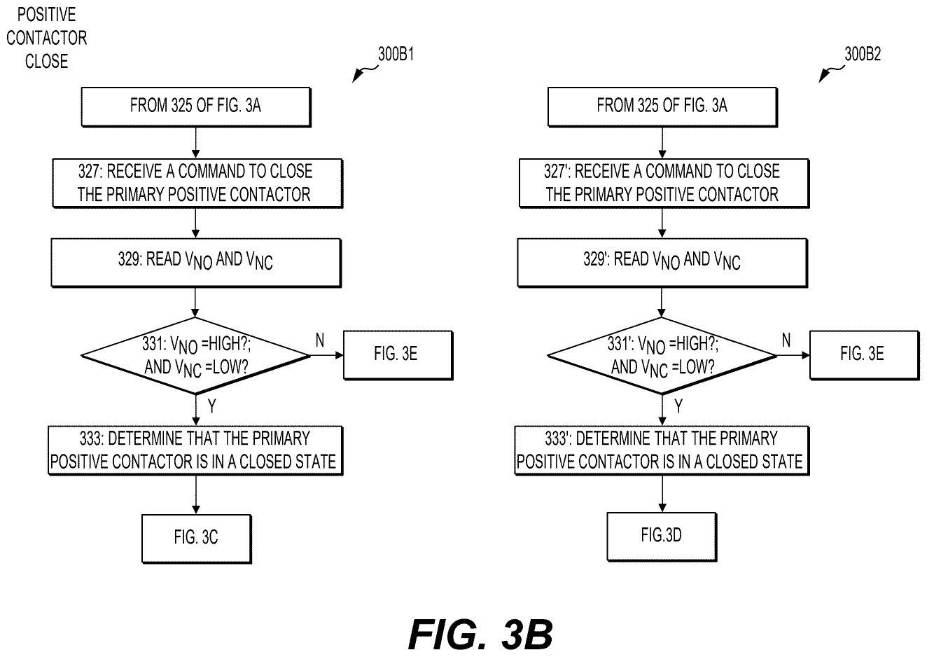

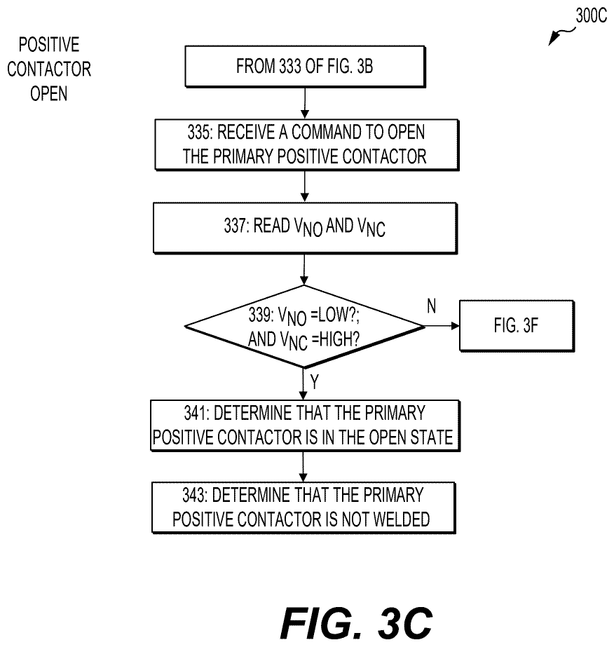

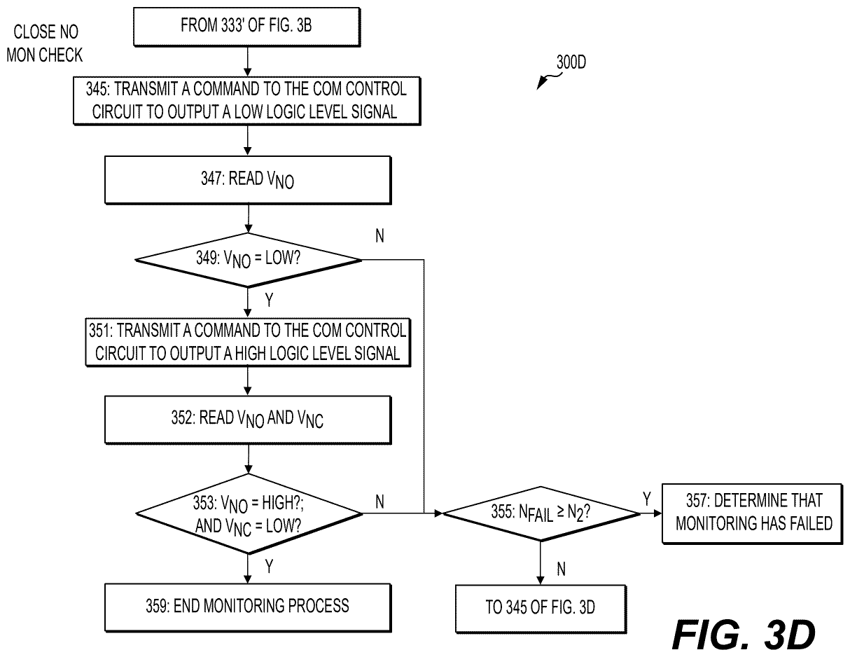

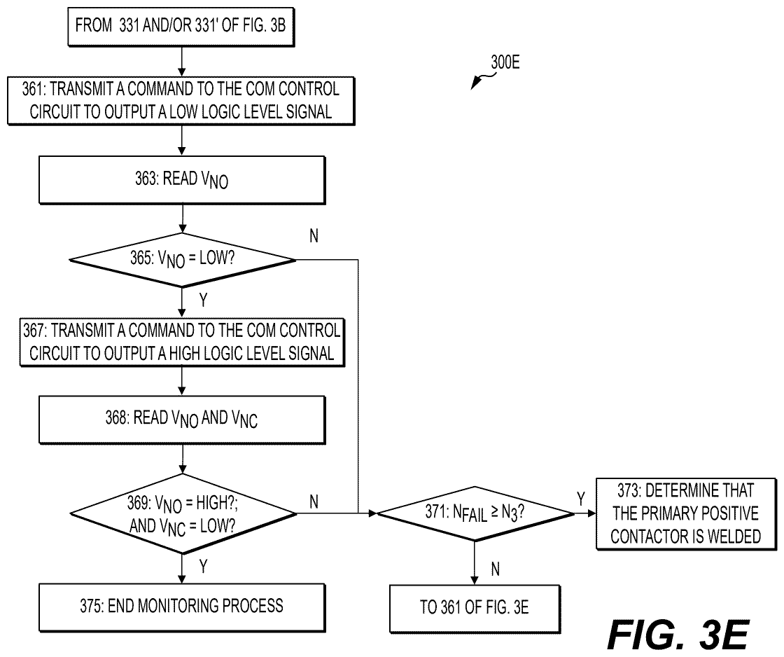

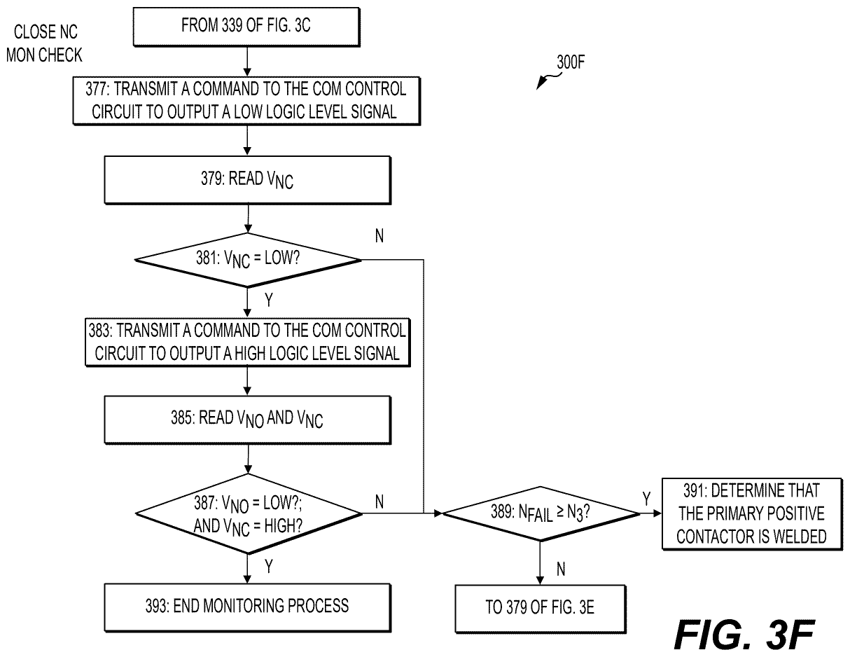

In some examples, the subpack microprocessor 114 may be configured to determine whether the battery system 100 (e.g., battery subpack 110) is in an abnormal state based on the information about the electrical signal from the NC pin 203 and/or the information about the electrical signal from the NO pin 205. Examples of the abnormal state of the battery system 100 may include the primary positive contactor being welded and a malfunctioning of one or more of the monitoring circuits (e.g., COM control circuit 125, NC sensing circuit 126, and NO sensing circuit 127). More details of the abnormal state detection/monitoring methods are provided with respect to the processes illustrated in FIGS. 3A-3F.

FIGS. 3A-3F illustrate a flow diagram of example methods 300A-300F for monitoring/detecting an abnormal state of a battery system according to some example embodiments of the present disclosure. Although the example methods 300A-300F are described with reference to the flow diagram illustrated in FIGS. 3A-3F, it will be appreciated that many other methods of performing the acts associated with the methods may be used. For example, the order of some of the blocks may be changed, certain blocks may be combined with other blocks, and some of the blocks described may be optional.

In some examples, the master microprocessor 131 and/or the subpack microprocessor 114 may perform one or more portions of the processes 300A-300F and may be implemented using, for instance, a chip set including a processor and a memory.

In the illustrated example, the subpack microprocessor 114 may read an electrical signal (Vcom) output from the COM control circuit 125 (block 301). For example, the subpack microprocessor 114 may receive information about the electrical signal (Vcom) that is provided to the COM pin 201 from the COM control circuit 125. Then, the subpack microprocessor 114 may determine whether the electrical signal (Vcom) from the COM control circuit 125 is a low logic level signal (block 303).

Responsive to determining that the electrical signal (Vcom) from the COM control circuit 125 is not a low logic level signal, the subpack microprocessor 114 may determine that the monitoring of the electrical signal (Vcom) from the COM control circuit 125 has failed (block 305). For example, the subpack microprocessor 114 may determine that there is an error in the COM control circuit 125.

Responsive to determining that the electrical signal (Vcom) from the COM control circuit 125 is a low logic level signal, the subpack microprocessor 114 may transmit a command to the COM control circuit 125 to output a high logic level signal (block 307). In response, the COM control circuit 125 may provide a high logic level signal to the COM pin 201. Then, the subpack microprocessor 114 may read the electrical signal (Vcom) output from the COM control circuit 125, for example, through the COM control circuit 125 (block 309).

After reading the electrical signal (Vcom), the subpack microprocessor 114 may determine whether the electrical signal (Vcom) from the COM control circuit 125 is a high logic level signal (block 311). Responsive to determining that the electrical signal (Vcom) from the COM control circuit 125 is not a high logic level signal, the subpack microprocessor 114 may determine that the monitoring of the electrical signal (Vcom) from the COM control circuit 125 has failed (block 313). For example, the subpack microprocessor 114 may determine that there is an error in the COM control circuit 125.

Responsive to determining that the electrical signal (Vcom) from the COM control circuit 125 is a high logic level signal, the subpack microprocessor 114 may read an electrical signal (V_{NO}) output from the NO pin 205 and an electrical signal (V_{NC}) output from the NC pin 203 (block 315). For example, the subpack microprocessor 114 may receive information about an electrical signal (V_{NO}) from the NO pin 205 from the NO sensing circuit 127, and receive information about an electrical signal (V_{NC}) from the NC pin 203 from the NC sensing circuit 126.

Then, the subpack microprocessor 114 may determine whether the electrical signal (V_{NO}) from the NO pin 205 is a low logic level signal, and whether the electrical signal (V_{NC}) from the NC pin 203 is a high logic level signal (block 317). Responsive to determining that the electrical signal (V_{NO}) from the NO pin 205 is not a low logic level signal and/or the electrical signal (V_{NC}) from the NC pin 203 is not a high logic level signal, the subpack microprocessor 114 may determine whether the number of times (N_{fail}) that the answer to block 317 was “No” is equal to or greater than a first predetermined number of times (N₁) (block 319). The first predetermined number of times (N₁) may be equal to or greater than 2 (e.g., 2, 3, 4, 5, . . . ). In some examples, the number of times (N_{fail}) that the answer to block 317 was “No” may be reset to “0” when the battery system is rebooted and/or according to a predetermined battery subpack control configuration (e.g., after a predetermined event, after a predetermined amount of time, etc.).

Responsive to determining that the number of times (N_{fail}) that the answer to block 317 was “No” is equal to or greater than the first predetermined number of times (N₁), the subpack microprocessor 114 may determine that the monitoring of the electrical signals (V_{NO}, V_{NC}) from the NO pin 205 and the NC pin 203 has failed (block 323). For example, the subpack microprocessor 114 may determine that there is an error in the NO sensing circuit 127 and/or the NC sensing circuit 126.

In some examples, if the number of times (N_{fail}) that the answer to block 317 was “No” is less than the first predetermined number of times (N₁), the subpack microprocessor 114 may repeat the steps from block 309. In some other examples, if the number of times (N_{fail}) that the answer to block 317 was “No” is less than the first predetermined number of times (N₁), the subpack microprocessor 114 may repeat the steps from block 315 or any other suitable blocks in FIG. 3A.

If it is determined that the electrical signal (V_{NO}) from the NO pin 205 is a low logic level signal and the electrical signal (V_{NC}) from the NC pin 203 is a high logic level signal, the subpack microprocessor 114 may determine that the primary positive contactor 115 is in an open state (block 325), and the method may proceed with the steps illustrated in FIG. 3B.

In some examples, the method 300A illustrated in FIG. 3A may be implemented as a start-up process (e.g., when the system 100 is started). In some examples, throughout the method 300A, it is assumed that the primary positive contactor 115 is in an open state. For example, throughout the method 300A, it is assumed that the BDU 108 and/or the subpack microprocessor 114 is transmitting a command to open the primary positive contactor 115. The method 300A illustrated in FIG. 3A may be implemented to ensure that there are no errors in the monitoring functions of one or more components of the BECM 106 (e.g., COM control circuit 125, NC sensing circuit 126, and NO sensing circuit 127), for example, before conducting a diagnostic for contactor welding.

Referring to FIG. 3B, in the method 300B1, the subpack microprocessor 114 may transmit a command to close the primary positive contactor 115 (block 327). For example, the subpack microprocessor 114 may transmit a command to the HV controller 211 of the BDU 108 to close the primary positive contactor 115 (and/or the negative contactor 105). In response, the HV controller 211 of the BDU 108 may transmit a command to close the primary positive contactor 115 (and/or the negative contactor 105).

While the subpack microprocessor 114 and/or the HV controller 211 is sending a command to close the primary positive contactor 115 (and/or the negative contactor 105) or after such command is sent out, the subpack microprocessor 114 may read the electrical signal (V_{NO}) output from the NO pin 205 and the electrical signal (V_{NC}) output from the NC pin 203 (block 329), and determine whether the electrical signal (V_{NO}) from the NO pin 205 is a high logic level signal, and whether the electrical signal (V_{NC}) from the NC pin 203 is a low logic level signal (block 331). Responsive to determining that the electrical signal (V_{NO}) from the NO pin 205 is not a high logic level signal and/or the electrical signal (V_{NC}) from the NC pin 203 is not a low logic level signal, the method may proceed with the steps illustrated in FIG. 3E.

If it is determined that the electrical signal (V_{NO}) from the NO pin 205 is a high logic level signal and the electrical signal (V_{NC}) from the NC pin 203 is a low logic level signal, the subpack microprocessor 114 may determine that the primary positive contactor 115 is in a closed state (block 333) and the method may proceed with the steps illustrated in FIG. 3C.

In some examples, subsequent to determining that the primary positive contactor 115 is in an open state at block 325, the subpack microprocessor 114 may proceed with the steps according to the method 300B2. The method 300B2 may be almost identical to the method 300B1 except that, after block 333′, the subpack microprocessor 114 may proceed with the steps illustrated in FIG. 3D instead of FIG. 3C.

Referring to FIG. 3C, the subpack microprocessor 114 may transmit a command to open the primary positive contactor 115 (block 335). For example, the subpack microprocessor 114 may transmit a command to the HV controller 211 of the BDU 108 to open the primary positive contactor 115 (and the negative contactor 105). In response, the HV controller 211 of the BDU 108 may transmit a command to close the primary positive contactor 115 (and the negative contactor 105). In some examples, an absence of any command from the subpack microprocessor 114 to the HV controller 211 may serve as a command to open the primary positive contactor 115 (and/or the negative contactor 105).

While the subpack microprocessor 114 and/or the HV controller 211 is sending a command to open the primary positive contactor 115 (and/or the negative contactor 105) or after such command is sent out, the subpack microprocessor 114 may read the electrical signal (V_{NO}) output from the NO pin 205 and the electrical signal (V_{NC}) output from the NC pin 203 (block 337), and determine whether the electrical signal (V_{NO}) from the NO pin 205 is a low logic level signal, and whether the electrical signal (V_{NC}) from the NC pin 203 is a high logic level signal (block 339). Responsive to determining that the electrical signal (V_{NO}) from the NO pin 205 is not a low logic level signal and/or the electrical signal (V_{NC}) from the NC pin 203 is not a high logic level signal, the method may proceed with the steps illustrated in FIG. 3F.

If it is determined that the electrical signal (V_{NO}) from the NO pin 205 is a low logic level signal and the electrical signal (V_{NC}) from the NC pin 203 is a high logic level signal, the subpack microprocessor 114 may determine that the primary positive contactor 115 is in the open state (block 341). The subpack microprocessor 114 may also determine that the primary positive contactor 115 is not welded (block 343).

Referring to FIG. 3D, in the illustrated example, the subpack microprocessor 114 may transmit a command to the COM control circuit 125 to output a low logic level signal (block 345). For example, after determining that the primary positive contactor is in a closed state at block 333′, the subpack microprocessor 114 may transmit a command to the COM control circuit 125 to output a low logic level signal. In response, the COM control circuit 125 may provide a low logic level signal to the COM pin 201. Then, the subpack microprocessor 114 may read the electrical signal (V_{NO}) output from the NO sensing circuit 127 (block 347). After reading the electrical signal (V_{NO}), the subpack microprocessor 114 may determine whether the electrical signal (V_{NO}) from the NO sensing circuit 127 is a low logic level signal (block 349).

Responsive to determining that the electrical signal (V_{NO}) from the NO sensing circuit 127 is not a low logic level signal, the method may proceed to block 335, which will be discussed in more detail below. If it is determined that the electrical signal (V_{NO}) from the NO sensing circuit 127 is a low logic level signal, the subpack microprocessor 114 may transmit a command to the COM control circuit 125 to output a high logic level signal (block 351). In response, the COM control circuit 125 may provide a high logic level signal to the COM pin 201.

Then, the subpack microprocessor 114 may read the electrical signal (V_{NO}) output from the NO pin 205 and the electrical signal (V_{NC}) output from the NC pin 203 (block 352) and determine whether the electrical signal (V_{NO}) from the NO pin 205 is a high logic level signal, and whether the electrical signal (V_{NC}) from the NC pin 203 is a low logic level signal (block 353). If it is determined that the electrical signal (V_{NO}) from the NO pin 205 is a high logic level signal and the electrical signal (V_{NC}) from the NC pin 203 is a low logic level signal, the subpack microprocessor 114 may end the monitoring process (block 359). In some examples, the subpack microprocessor 114 may end the monitoring process for a predetermined amount of time (e.g., 1 minute, 1 hour, 1 day, etc.) and restart the monitoring process (e.g., from block 301 or block 327/327′) after the predetermined amount of time. In some examples, the subpack microprocessor 114 may also determine that the primary positive contactor is not welded at block 359. In other examples, the method may proceed with the steps illustrated in FIG. 3C when the answer to block 353 is “Yes”.

Responsive to determining that i) the electrical signal (V_{NO}) from the NO pin 205 is not a high logic level signal and/or the electrical signal (V_{NC}) from the NC pin 203 is not a low logic level signal (from block 353) and/or ii) the electrical signal (V_{NO}) from the NO sensing circuit 127 is not a low logic level signal (from block 349), the subpack microprocessor 114 may determine whether the number of times (N_{fail}) that the answer to block 349 and/or 353 was “No” is equal to or greater than a second predetermined number of times (N₂) (block 355). The second predetermined number of times (N₂) may be equal to or greater than 2 (e.g., 2, 3, 4, 5, . . . ). In some examples, the number of times (N_{fail}) that the answer to block 349 and/or 353 was “No” may be reset to “0” when the battery system is rebooted and/or according to a predetermined battery subpack control configuration (e.g., after a predetermined event, after a predetermined amount of time, etc.).

Responsive to determining that the number of times (N_{fail}) that the answer to block 349 and/or 353 was “No” is equal to or greater than the second predetermined number of times (N₂), the subpack microprocessor 114 may determine that the monitoring of the electrical signals (V_{NO}, V_{NC}) from the NO pin 205 and the NC pin 203 has failed (block 357). For example, the subpack microprocessor 114 may determine that there is an error in the NO sensing circuit 127 and/or the NC sensing circuit 126. In some examples, if the number of times (N_{fail}) that the answer to block 349 and/or 353 was “No” is less than the second predetermined number of times (N₂), the subpack microprocessor 114 may repeat the steps from block 345 or any other suitable block in FIG. 3D.

Referring to FIG. 3E, in the illustrated example, the subpack microprocessor 114 may transmit a command to the COM control circuit 125 to output a low logic level signal (block 361). For example, responsive to determining that the electrical signal (V_{NO}) from the NO pin 205 is not a high logic level signal and/or the electrical signal (V_{NC}) from the NC pin 203 is not a low logic level signal at block 331 or block 331′, the subpack microprocessor 114 may transmit a command to the COM control circuit 125 to output a low logic level signal. In response, the COM control circuit 125 may provide a low logic level signal to the COM pin 201.

Then, the subpack microprocessor 114 may read the electrical signal (V_{NO}) output from the NO sensing circuit 127 (block 363). After reading the electrical signal (V_{NO}), the subpack microprocessor 114 may determine whether the electrical signal (V_{NO}) from the NO sensing circuit 127 is a low logic level signal (block 365).

Responsive to determining that the electrical signal (V_{NO}) from the NO sensing circuit 127 is not a low logic level signal, the method may proceed to block 371, which will be discussed in more detail below. If it is determined that the electrical signal (V_{NO}) from the NO sensing circuit 127 is a low logic level signal, the subpack microprocessor 114 may transmit a command to the COM control circuit 125 to output a high logic level signal (block 367). In response, the COM control circuit 125 may provide a high logic level signal to the COM pin 201.

Then, the subpack microprocessor 114 may read the electrical signal (V_{NO}) output from the NO pin 205 and the electrical signal (V_{NC}) output from the NC pin 203 (block 368) and determine whether the electrical signal (V_{NO}) from the NO pin 205 is a high logic level signal, and whether the electrical signal (V_{NC}) from the NC pin 203 is a low logic level signal (block 369). If it is determined that the electrical signal (V_{NO}) from the NO pin 205 is a high logic level signal and the electrical signal (V_{NC}) from the NC pin 203 is a low logic level signal, the subpack microprocessor 114 may end the monitoring process (block 375). In some examples, the subpack microprocessor 114 may end the monitoring process for a predetermined amount of time (e.g., 1 minute, 1 hour, 1 day, etc.) and restart the monitoring process (from block 301 or block 327/327′) after the predetermined amount of time. In some examples, the subpack microprocessor 114 may also determine that the primary positive contactor is not welded at block 375.

Responsive to determining that i) the electrical signal (V_{NO}) from the NO pin 205 is not a high logic level signal and/or the electrical signal (V_{NC}) from the NC pin 203 is not a low logic level signal (from block 369) and/or ii) the electrical signal (V_{NO}) from the NO sensing circuit 127 is not a low logic level signal (from block 365), the subpack microprocessor 114 may determine whether the number of times (N_{fail}) that the answer to block 365 and/or 369 was “No” is equal to or greater than a third predetermined number of times (N₃) (block 371). The third predetermined number of times (N₃) may be equal to or greater than 2 (e.g., 2, 3, 4, 5, . . . ). In some examples, the number of times (N_{fail}) that the answer to block 365 and/or 369 was “No” may be reset to “0” when the battery system is rebooted and/or according to a predetermined battery subpack control configuration (e.g., after a predetermined event, after a predetermined amount of time, etc.).

Responsive to determining that the number of times (N_{fail}) that the answer to block 365 and/or 369 was “No” is equal to or greater than the third predetermined number of times (N₃), the subpack microprocessor 114 may determine that the primary positive contactor 115 is welded (block 373). For example, the subpack microprocessor 114 may determine that the primary positive contactor 115 is stuck open as a result of a welding. In some examples, if the number of times (N_{fail}) that the answer to block 365 and/or 369 was “No” is less than the third predetermined number of times (N₃), the subpack microprocessor 114 may repeat the steps from block 361 or any other suitable block in FIG. 3E.

Referring to FIG. 3F, in the illustrated example, the subpack microprocessor 114 may transmit a command to the COM control circuit 125 to output a low logic level signal (block 377). For example, responsive to determining that the electrical signal (V_{NO}) from the NO pin 205 is not a low logic level signal and/or the electrical signal (V_{NC}) from the NC pin 203 is not a high logic level signal at block 339, the subpack microprocessor 114 may transmit a command to the COM control circuit 125 to output a low logic level signal. In response, the COM control circuit 125 may provide a low logic level signal to the COM pin 201. Then, the subpack microprocessor 114 may read the electrical signal (V_{NC}) output from the NC sensing circuit 126 (block 379). After reading the electrical signal (V_{NC}), the subpack microprocessor 114 may determine whether the electrical signal (V_{NC}) from the NC sensing circuit 126 is a low logic level signal (block 381).

Responsive to determining that the electrical signal (V_{NC}) from the NC sensing circuit 126 is not a low logic level signal, the method may proceed to block 389, which will be discussed in more detail below. If it is determined that the electrical signal (V_{NC}) from the NC sensing circuit 126 is a low logic level signal, the subpack microprocessor 114 may transmit a command to the COM control circuit 125 to output a high logic level signal (block 383). In response, the COM control circuit 125 may provide a high logic level signal to the COM pin 201.

Then, the subpack microprocessor 114 may read the electrical signal (V_{NO}) output from the NO pin 205 and the electrical signal (V_{NC}) output from the NC pin 203 (block 385) and determine whether the electrical signal (V_{NO}) from the NO pin 205 is a low logic level signal, and whether the electrical signal (V_{NC}) from the NC pin 203 is a high logic level signal (block 387). If it is determined that the electrical signal (V_{NO}) from the NO pin 205 is a low logic level signal and the electrical signal (V_{NC}) from the NC pin 203 is a high logic level signal, the subpack microprocessor 114 may end the monitoring process (block 393). In some examples, the subpack microprocessor 114 may end the monitoring process for a predetermined amount of time (e.g., 1 minute, 1 hour, 1 day, etc.) and restart the monitoring process (e.g., from block 301 or block 327/327′) after the predetermined amount of time. In some examples, the subpack microprocessor 114 may also determine that the primary positive contactor is not welded at block 393.

Responsive to determining that i) the electrical signal (V_{NO}) from the NO pin 205 is not a low logic level signal and/or the electrical signal (V_{NC}) from the NC pin 203 is not a high logic level signal (from block 387) and/or ii) the electrical signal (V_{NC}) from the NC sensing circuit 126 is not a low logic level signal (from block 381), the subpack microprocessor 114 may determine whether the number of times (N_{fail}) that the answer to block 381 and/or 387 was “No” is equal to or greater than a fourth predetermined number of times (N₄) (block 389). The fourth predetermined number of times (N₄) may be equal to or greater than 2 (e.g., 2, 3, 4, 5, . . . ). In some examples, the number of times (N_{fail}) that the answer to block 381 and/or 387 was “No” may be reset to “0” when the battery system is rebooted and/or according to a predetermined battery subpack control configuration (e.g., after a predetermined event, after a predetermined amount of time, etc.).

Responsive to determining that the number of times (N_{fail}) that the answer to block 381 and/or 387 was “No” is equal to or greater than the fourth predetermined number of times (N₄), the subpack microprocessor 114 may determine that the primary positive contactor 115 is welded (block 391). For example, the subpack microprocessor 114 may determine that the primary positive contactor 115 is stuck closed as a result of a welding. In some examples, if the number of times (N_{fail}) that the answer to block 381 and/or 387 was “No” is less than the fourth predetermined number of times (N₄), the subpack microprocessor 114 may repeat the steps from block 377 or any other suitable block in FIG. 3F.

In some examples, all or some of the functions performed by the subpack microprocessor 114 may be performed by the master microprocessor 131. In some examples, one of the subpack microprocessors 114 may serve as a master microprocessor performing all or some of the functions performed by the master microprocessor 131. In this case, there may be no separate master controller 130/master microprocessor 131. In some examples, all or some of the functions performed by the master microprocessor 131 may be performed by one or more of the subpack microprocessors 114.

In some examples, the subpack microprocessor 114 may perform a contactor state detection/monitoring function according to a predetermined detection/monitoring configuration. For example, the subpack microprocessor 114 may determine whether the battery system 100 and/or the battery subpack 110 is in an abnormal state based on a table having information about normal/abnormal operation conditions of the contactors 104, 105.

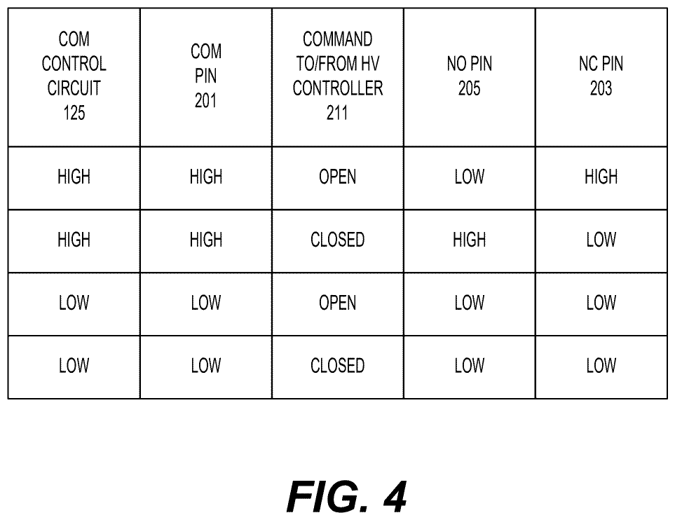

FIG. 4. Illustrates an example table showing normal operation conditions of the contactors 104, 105. For example, when the HV controller 211 is commanded, from the subpack microprocessor 114, to open the primary positive contactor 115 (or the HV controller 211 transmits a command to open the primary positive contactor 115) and the COM control circuit 125 is providing a high logic level signal to the COM pin 201, the electrical signals from the NO pin 205 and the NC pin 203 are expected to be a low logic level signal and a high logic level signal, respectively, in a normal operation condition.

In some examples, the subpack microprocessor 114 may monitor the electrical signals from the COM pin 201, NC pin 203, and NO pin 205 continuously (e.g., every milliseconds), through the COM control circuit 125, NC sensing circuit 126, and NO sensing circuit 127, and compare the data (e.g., information about the electrical signals of these pins) with the information in the table to detect any error in the circuit. When the subpack microprocessor 114 determines that the monitored data do not match the information in the table (e.g., information about the normal operation conditions), the subpack microprocessor 114 may generate an error notification indicating that the battery system 100 and/or the battery subpack 110 may be in an abnormal condition.

When the subpack microprocessor 114 determines that the monitored data do not match the information in the table (e.g., information about the normal operation conditions), the subpack microprocessor 114 may perform additional detection functions to find the specific reasons for the error (e.g., contactor welding, errors in sensing circuits or any other circuits of the battery subpack 110). In some examples, at this point, the subpack microprocessor 114 may perform all or part of the steps illustrated in FIGS. 3A-3F to find the specific reasons for the error.

In some examples, when the subpack microprocessor 114 determines that the battery system 100 and/or the battery subpack 110 is in an abnormal state, the subpack microprocessor 114 may initiate one or more corrective actions. For example, if the subpack microprocessor 114 determines that the primary positive contactor 115 is welded in a closed position, the subpack microprocessor 114 may transmit a command to isolate the affected battery subpack 110 from the rest of the battery system 100 to prevent potential damage to other components. This isolation may be achieved by opening other contactors in the system or by activating dedicated isolation circuits.

In some examples, when a welded contactor is detected, the subpack microprocessor 114 may also initiate a controlled shutdown sequence of the affected battery subpack 110 while maintaining operation of other battery subpacks in the system. The subpack microprocessor 114 may transmit a notification to the master microprocessor 131 indicating the need for maintenance or replacement of the welded contactor. The notification may include diagnostic information such as the specific type of welding condition detected (e.g., stuck open or stuck closed) and the number of failed detection attempts.

In some examples, the diagnostic information transmitted by the subpack microprocessor 114 to the master microprocessor 131 may be used by service technicians to efficiently locate and replace the welded contactor. The diagnostic information, which includes the specific type of welding condition and location of the affected battery subpack 110, allows service technicians to quickly identify and access the faulty component for replacement. This targeted diagnostic approach helps minimize system downtime during maintenance operations.

In some examples, if the subpack microprocessor 114 detects errors in the sensing circuits (e.g., COM control circuit 125, NC sensing circuit 126, or NO sensing circuit 127), it may implement redundant monitoring pathways or activate backup sensing circuits, if available. The subpack microprocessor 114 may also adjust the monitoring frequency or implement additional verification steps to ensure reliable operation despite the compromised sensing circuit.

In some examples, the subpack microprocessor 114 may store information about detected abnormal states and corrective actions in a non-volatile memory for additional monitoring or maintenance purposes. This information may include timestamps, specific error conditions, and the effectiveness of implemented corrective actions, which can be used for predictive maintenance and system optimization.

Although the table in FIG. 4. only shows normal operation conditions, the table may include abnormal operation conditions. In some examples, an abnormal operation condition may refer to any condition that does not match the normal conditions shown in FIG. 4. For examples, when the information in the first, second, third, fourth, and fifth columns are “High,” “High,” “Open,” “High,” and “Low,” respectively, the system 100 may be in an abnormal condition. In some examples, the normal/abnormal operation conditions may be stored (e.g., in a storage device) in the system 100 in any other suitable forms/data structures, and the subpack microprocessor 114 may perform the monitoring function based on this information.

The general discussion of this disclosure provides a brief, general description of a suitable computing environment in which the present disclosure may be implemented. In some examples, any of the disclosed systems, methods, and/or graphical user interfaces may be executed by or implemented by a computing system consistent with or similar to that depicted and/or explained in this disclosure. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server and/or from a server to the mobile device. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution. In some examples, the subpack microprocessor 114 and/or the master microprocessor 131 may be part of and/or associated with a computing system/special purpose computer described above (e.g., a processor).

The terminology used above may be interpreted in its broadest reasonable manner, even though it is being used in conjunction with a detailed description of certain specific examples of the present disclosure. Indeed, certain terms may even be emphasized above; however, any terminology intended to be interpreted in any restricted manner will be overtly and specifically defined as such in this Detailed Description section. Both the foregoing general description and the detailed description are exemplary and explanatory only and are not restrictive of the features, as claimed.

As used herein, the terms “comprises,” “comprising,” “having,” including,” or other variations thereof, are intended to cover a non-exclusive inclusion such that a process, method, article, or apparatus that comprises a list of elements does not include only those elements, but may include other elements not expressly listed or inherent to such a process, method, article, or apparatus.

As used herein, “about,” “approximately,” “generally,” and “substantially” are understood to refer to numbers in a range of numerals, for example the range of −10% to +10% of the referenced number, preferably −5% to +5% of the referenced number, more preferably −1% to +1% of the referenced number, most preferably −0.1% to +0.1% of the referenced number. Moreover, these numerical ranges should be construed as providing support for a claim directed to any number or subset of numbers in that range. For example, a disclosure of from 1 to 10 should be construed as supporting a range of from 1 to 5, from 3 to 6, from 1 to 9, from 2.5 to 4.7, from 2.2 to 9.9, and so forth.

As used herein, the term “electrically connected” may mean that the referenced elements are directly or indirectly connected in such a way as to allow electric current to flow between them.

It is noted that the hereinafter-used terms “attachable”, “attached”, “connectable”, and “connected” include, respectively, directly or indirectly attachable, directly or indirectly attached, directly or indirectly connectable, and directly or indirectly connected.

When the position relation between two parts is described using the terms such as “on,” “above,” “below,” “under,” and “next,” one or more parts may be positioned between the two parts unless the terms are used with the term “immediately” or “directly.” Similarly, as used herein, the terms “attachable”, “attached”, “connectable”, “connected” or any similar terms may include directly or indirectly attachable, directly or indirectly attached, directly or indirectly connectable, and directly or indirectly connected.

In those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

Additionally, in describing the components of the present invention, there may be terms used like first, second, A, B, (a), and (b). These may be for the purpose of differentiating one component from the other but not to imply or suggest the substances, order, sequence, or number of the components unless the context dictates otherwise.

The term “exemplary” is used in the sense of “example” rather than “ideal.” As used herein, the singular forms “a,” “an,” and “the” include plural reference unless the context dictates otherwise.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

Aspects of the present disclosure may provide a simple, cost-effective, and reliable solution for monitoring contactor state in high-voltage systems, thereby eliminating the need for complex circuitry and sensors, making it an attractive option for various applications.

### Examples

The present disclosure furthermore relates to the following aspects.

Example 1. A battery system comprising: a battery unit; a positive contactor having: a primary positive contactor electrically connected to a positive terminal of the battery unit; and an auxiliary positive contactor comprising a common (COM) pin, a normally-closed (NC) pin, and a normally-open (NO) pin, wherein the COM pin is configured to be electrically connected to the NC pin when the primary positive contactor is in an open state, and the COM pin is configured to be electrically connected to the NO pin when the primary positive contactor is in a closed state; a negative contactor electrically connected to a negative terminal of the battery unit; a microprocessor configured to control the positive contactor and the negative contactor; a COM control circuit configured to provide an electrical signal to the COM pin; an NC sensing circuit configured to monitor an electrical signal from the NC pin and transmit first information about the electrical signal from the NC pin to the microprocessor; an NO sensing circuit configured to monitor an electrical signal from the NO pin and transmit second information about the electrical signal from the NO pin to the microprocessor, wherein the microprocessor is configured to determine whether the battery system is in an abnormal state based on the first information about the electrical signal from the NC pin and the second information about the electrical signal from the NO pin.

Example 2. The battery system of example 1, wherein the abnormal state of the battery system comprises a state indicating the primary positive contactor being welded.

Example 3. The battery system of any one of examples 1-2, wherein the NC sensing circuit is configured to monitor the electrical signal from the NC pin at a first predetermined time interval, and the NO sensing circuit is configured to monitor the electrical signal from the NO pin at a second predetermined time interval.

Example 4. The battery system of example 3, wherein the first predetermined time interval and the second predetermined time interval are in a range of about 50 milliseconds to about 200 milliseconds.

Example 5. The battery system of any one of examples 1-4, further comprising a battery disconnect unit configured to open and close the primary positive contactor in response to a command from the microprocessor to open or close the primary positive contactor.

Example 6. The battery system of any one of examples 1-5, wherein the microprocessor is configured to: transmit a command to the COM control circuit to provide a high logic level signal to the COM pin; transmit a command to open the primary positive contactor; receive, from the NC sensing circuit, the first information about the electrical signal from the NC pin; receive, from the NO sensing circuit, the second information about the electrical signal from the NO pin; determine whether the electrical signal from the NC pin is a high logic level signal based on the first information about the electrical signal from the NC pin; and determine whether the electrical signal from the NO pin is a low logic level signal based on the second information about the electrical signal from the NC pin.

Example 7. The battery system of example 6, wherein, responsive to determining that the electrical signal from the NC pin is not the high logic level signal or the electrical signal from the NO pin is not the low logic level signal, the microprocessor is configured to: transmit a command to the COM control circuit to provide the low logic level signal to the COM pin; receive, from the NC sensing circuit, the first information about the electrical signal from the NC pin; determine whether the electrical signal from the NC pin is the low logic level signal based on the first information about the electrical signal from the NC pin; and responsive to determining that the electrical signal from the NC pin is the low logic level signal, transmit a command to the COM control circuit to provide the high logic level signal to the COM pin.

Example 8. The battery system of example 7, wherein, subsequent to transmitting the command to the COM control circuit to provide the high logic level signal to the COM pin, the microprocessor is configured to: receive, from the NC sensing circuit, the first information about the electrical signal from the NC pin; receive, from the NO sensing circuit, the second information about the electrical signal from the NO pin; determine whether the electrical signal from the NC pin is the high logic level signal based on the first information about the electrical signal from the NC pin; and determine whether the electrical signal from the NO pin is the low logic level signal based on the second information about the electrical signal from the NC pin.

Example 9. The battery system of example 8, wherein, responsive to determining that the electrical signal from the NC pin is not the high logic level and the electrical signal from the NO pin is not the low logic level signal, the microprocessor is configured to generate a notification indicating that the primary positive contactor is welded.

Example 10. A battery system comprising: one or more battery packs, each of the one or more battery packs comprising: a battery unit; a positive contactor having: a primary positive contactor electrically connected to a positive terminal of the battery unit and configured to move between a first state and a second state; and an auxiliary positive contactor comprising a common (COM) pin, a first pin, and a second pin, wherein the COM pin is configured to be electrically connected to the first pin when the primary positive contactor is in the first state, and the COM pin is configured to be electrically connected to the second pin when the primary positive contactor is in the second state; a negative contactor electrically connected to a negative terminal of the battery unit; a subpack microprocessor configured to control the positive contactor and the negative contactor; a battery disconnect unit configured to control the primary positive contactor to move between the first state and the second state in response to a command from the subpack microprocessor; a COM control circuit configured to provide an electrical signal to the COM pin; a first sensing circuit configured to monitor an electrical signal from the first pin and transmit first information about the electrical signal from the first pin to the subpack microprocessor; a second sensing circuit configured to monitor an electrical signal from the second pin and transmit second information about the electrical signal from the second pin to the subpack microprocessor, wherein the subpack microprocessor of the one or more battery packs is configured to determine whether the corresponding battery pack is in an abnormal state based on the first information about the electrical signal from the first pin and the second information about the electrical signal from the second pin.

Example 11. The battery system of example 10, wherein the abnormal state of the corresponding battery pack comprises a state indicating the primary positive contactor being welded.

Example 12. The battery system of any one of examples 10-11, further comprising a master microprocessor in electrical communication with the subpack microprocessor of each of the one or more battery packs, wherein the master microprocessor is configured to receive information about a state of the one or more battery packs.

Example 13. The battery system of any one of examples 10-12, wherein the subpack microprocessor is configured to: transmit a command to the COM control circuit to provide a high logic level signal to the COM pin; transmit a command to the battery disconnect unit to move the primary positive contactor to the first state; receive, from the first sensing circuit, the first information about the electrical signal from the first pin; receive, from the second sensing circuit, the second information about the electrical signal from the second pin; determine whether the electrical signal from the first pin is a high logic level signal based on the first information about the electrical signal from the first pin; and determine whether the electrical signal from the second pin is a low logic level signal based on the second information about the electrical signal from the first pin.

Example 14. The battery system of example 13, wherein, responsive to determining that the electrical signal from the first pin is not the high logic level signal or the electrical signal from the second pin is not the low logic level signal, the subpack microprocessor is configured to: transmit a command to the COM control circuit to provide the low logic level signal to the COM pin; receive, from the first sensing circuit, the first information about the electrical signal from the first pin; determine whether the electrical signal from the first pin is the low logic level signal based on the first information about the electrical signal from the first pin; and responsive to determining that the electrical signal from the first pin is the low logic level signal, transmit a command to the COM control circuit to provide the high logic level signal to the COM pin.

Example 15. The battery system of example 14, wherein, subsequent to transmitting the command to the COM control circuit to provide the high logic level signal to the COM pin, the subpack microprocessor is configured to: receive, from the first sensing circuit, the first information about the electrical signal from the first pin; receive, from the second sensing circuit, the second information about the electrical signal from the second pin; determine whether the electrical signal from the first pin is the high logic level signal based on the first information about the electrical signal from the first pin; and determine whether the electrical signal from the second pin is the low logic level signal based on the second information about the electrical signal from the first pin.

Example 16. The battery system of example 15, wherein, responsive to determining that the electrical signal from the first pin is not the high logic level and the electrical signal from the second pin is not the low logic level signal, the subpack microprocessor is configured to generate a notification indicating that the primary positive contactor is welded.

Example 17. A method of monitoring a state of a battery system, wherein the battery system comprises: a battery unit; a positive contactor having: a primary positive contactor electrically connected to a positive terminal of the battery unit and configured to move between a first state and a second state; and an auxiliary positive contactor comprising a common (COM) pin, a first pin, and a second pin, wherein the COM pin is configured to be electrically connected to the first pin when the primary positive contactor is in the first state, and the COM pin is configured to be electrically connected to the second pin when the primary positive contactor is in the second state; a negative contactor electrically connected to a negative terminal of the battery unit; a microprocessor configured to control the positive contactor and the negative contactor; a COM control circuit configured to provide an electrical signal to the COM pin; an NC sensing circuit configured to monitor an electrical signal from the first pin and transmit first information about the electrical signal from the first pin to the microprocessor; an NO sensing circuit configured to monitor an electrical signal from the second pin and transmit second information about the electrical signal from the second pin to the microprocessor, wherein the method comprises: determining, by the microprocessor, whether the battery system is in an abnormal state based on the first information about the electrical signal from the first pin and the second information about the electrical signal from the second pin.

Example 18. The method of example 17, comprising: transmitting, by the microprocessor, a command to the COM control circuit to provide a high logic level signal to the COM pin; transmitting, by the microprocessor, a command to move the primary positive contactor to the first state; receiving, by the microprocessor from the NC sensing circuit, the first information about the electrical signal from the first pin; receiving, by the microprocessor from the NO sensing circuit, the second information about the electrical signal from the second pin; determining, by the microprocessor, whether the electrical signal from the first pin is a high logic level signal based on the first information about the electrical signal from the first pin; and determining, by the microprocessor, whether the electrical signal from the second pin is a low logic level signal based on the second information about the electrical signal from the first pin.

Example 19. The method of example 18, comprising, responsive to determining that the electrical signal from the first pin is not the high logic level signal or the electrical signal from the second pin is not the low logic level signal: transmitting, by the microprocessor, a command to the COM control circuit to provide the low logic level signal to the COM pin; receiving, by the microprocessor from the NC sensing circuit, the first information about the electrical signal from the first pin; determining, by the microprocessor, whether the electrical signal from the first pin is the low logic level signal based on the first information about the electrical signal from the first pin; and responsive to determining that the electrical signal from the first pin is the low logic level signal, transmitting, by the microprocessor, a command to the COM control circuit to provide the high logic level signal to the COM pin.

Example 20. The method of example 19, comprising, subsequent to transmitting the command to the COM control circuit to provide the high logic level signal to the COM pin: receiving, by the microprocessor from the NC sensing circuit, the first information about the electrical signal from the first pin; receiving, by the microprocessor from the NO sensing circuit, the second information about the electrical signal from the second pin; determining, by the microprocessor, whether the electrical signal from the first pin is the high logic level signal based on the first information about the electrical signal from the first pin; determining, by the microprocessor, whether the electrical signal from the second pin is the low logic level signal based on the second information about the electrical signal from the first pin; and responsive to determining that the electrical signal from the first pin is not the high logic level and the electrical signal from the second pin is not the low logic level signal, generating, by the microprocessor, a notification indicating that the primary positive contactor is welded.

What is claimed is:

1. A battery system comprising:
a battery unit;
a positive contactor having:
a primary positive contactor electrically connected to a positive terminal of the battery unit; and
an auxiliary positive contactor comprising a common (COM) pin, a normally-closed (NC) pin, and a normally-open (NO) pin, wherein the COM pin is configured to be electrically connected to the NC pin when the primary positive contactor is in an open state, and the COM pin is configured to be electrically connected to the NO pin when the primary positive contactor is in a closed state;
a negative contactor electrically connected to a negative terminal of the battery unit;
a microprocessor configured to control the positive contactor and the negative contactor;
a COM control circuit configured to provide an electrical signal to the COM pin;
an NC sensing circuit configured to monitor an electrical signal from the NC pin and transmit first information about the electrical signal from the NC pin to the microprocessor;
an NO sensing circuit configured to monitor an electrical signal from the NO pin and transmit second information about the electrical signal from the NO pin to the microprocessor,
wherein the microprocessor is configured to determine whether the battery system is in an abnormal state based on the first information about the electrical signal from the NC pin and the second information about the electrical signal from the NO pin.

2. The battery system of claim 1, wherein the abnormal state of the battery system comprises a state indicating the primary positive contactor being welded.

3. The battery system of claim 1, wherein the NC sensing circuit is configured to monitor the electrical signal from the NC pin at a first predetermined time interval, and the NO sensing circuit is configured to monitor the electrical signal from the NO pin at a second predetermined time interval.

4. The battery system of claim 3, wherein the first predetermined time interval and the second predetermined time interval are in a range of about 50 milliseconds to about 200 milliseconds.

5. The battery system of claim 1, further comprising a battery disconnect unit configured to open and close the primary positive contactor in response to a command from the microprocessor to open or close the primary positive contactor.

6. The battery system of claim 1, wherein the microprocessor is configured to:
transmit a command to the COM control circuit to provide a high logic level signal to the COM pin;
transmit a command to open the primary positive contactor;
receive, from the NC sensing circuit, the first information about the electrical signal from the NC pin;
receive, from the NO sensing circuit, the second information about the electrical signal from the NO pin;
determine whether the electrical signal from the NC pin is a high logic level signal based on the first information about the electrical signal from the NC pin; and
determine whether the electrical signal from the NO pin is a low logic level signal based on the second information about the electrical signal from the NC pin.

7. The battery system of claim 6, wherein, responsive to determining that the electrical signal from the NC pin is not the high logic level signal or the electrical signal from the NO pin is not the low logic level signal, the microprocessor is configured to:
transmit a command to the COM control circuit to provide the low logic level signal to the COM pin;
receive, from the NC sensing circuit, the first information about the electrical signal from the NC pin;
determine whether the electrical signal from the NC pin is the low logic level signal based on the first information about the electrical signal from the NC pin; and
responsive to determining that the electrical signal from the NC pin is the low logic level signal, transmit a command to the COM control circuit to provide the high logic level signal to the COM pin.

8. The battery system of claim 7, wherein, subsequent to transmitting the command to the COM control circuit to provide the high logic level signal to the COM pin, the microprocessor is configured to:
receive, from the NC sensing circuit, the first information about the electrical signal from the NC pin;
receive, from the NO sensing circuit, the second information about the electrical signal from the NO pin;
determine whether the electrical signal from the NC pin is the high logic level signal based on the first information about the electrical signal from the NC pin; and
determine whether the electrical signal from the NO pin is the low logic level signal based on the second information about the electrical signal from the NC pin.

9. The battery system of claim 8, wherein, responsive to determining that the electrical signal from the NC pin is not the high logic level and the electrical signal from the NO pin is not the low logic level signal, the microprocessor is configured to generate a notification indicating that the primary positive contactor is welded.

10. A battery system comprising:
one or more battery packs, each of the one or more battery packs comprising:
a battery unit;
a positive contactor having:
a primary positive contactor electrically connected to a positive terminal of the battery unit and configured to move between a first state and a second state; and
an auxiliary positive contactor comprising a common (COM) pin, a first pin, and a second pin, wherein the COM pin is configured to be electrically connected to the first pin when the primary positive contactor is in the first state, and the COM pin is configured to be electrically connected to the second pin when the primary positive contactor is in the second state;
a negative contactor electrically connected to a negative terminal of the battery unit;
a subpack microprocessor configured to control the positive contactor and the negative contactor;
a battery disconnect unit configured to control the primary positive contactor to move between the first state and the second state in response to a command from the subpack microprocessor;
a COM control circuit configured to provide an electrical signal to the COM pin;
a first sensing circuit configured to monitor an electrical signal from the first pin and transmit first information about the electrical signal from the first pin to the subpack microprocessor;
a second sensing circuit configured to monitor an electrical signal from the second pin and transmit second information about the electrical signal from the second pin to the subpack microprocessor,
wherein the subpack microprocessor of the one or more battery packs is configured to determine whether the corresponding battery pack is in an abnormal state based on the first information about the electrical signal from the first pin and the second information about the electrical signal from the second pin.

11. The battery system of claim 10, wherein the abnormal state of the corresponding battery pack comprises a state indicating the primary positive contactor being welded.

12. The battery system of claim 10, further comprising a master microprocessor in electrical communication with the subpack microprocessor of each of the one or more battery packs, wherein the master microprocessor is configured to receive information about a state of the one or more battery packs.

13. The battery system of claim 10, wherein the subpack microprocessor is configured to:
transmit a command to the COM control circuit to provide a high logic level signal to the COM pin;
transmit a command to the battery disconnect unit to move the primary positive contactor to the first state;
receive, from the first sensing circuit, the first information about the electrical signal from the first pin;
receive, from the second sensing circuit, the second information about the electrical signal from the second pin;
determine whether the electrical signal from the first pin is a high logic level signal based on the first information about the electrical signal from the first pin; and
determine whether the electrical signal from the second pin is a low logic level signal based on the second information about the electrical signal from the first pin.

14. The battery system of claim 13, wherein, responsive to determining that the electrical signal from the first pin is not the high logic level signal or the electrical signal from the second pin is not the low logic level signal, the subpack microprocessor is configured to:
transmit a command to the COM control circuit to provide the low logic level signal to the COM pin;
receive, from the first sensing circuit, the first information about the electrical signal from the first pin;
determine whether the electrical signal from the first pin is the low logic level signal based on the first information about the electrical signal from the first pin; and
responsive to determining that the electrical signal from the first pin is the low logic level signal, transmit a command to the COM control circuit to provide the high logic level signal to the COM pin.

15. The battery system of claim 14, wherein, subsequent to transmitting the command to the COM control circuit to provide the high logic level signal to the COM pin, the subpack microprocessor is configured to:
receive, from the first sensing circuit, the first information about the electrical signal from the first pin;
receive, from the second sensing circuit, the second information about the electrical signal from the second pin;
determine whether the electrical signal from the first pin is the high logic level signal based on the first information about the electrical signal from the first pin; and
determine whether the electrical signal from the second pin is the low logic level signal based on the second information about the electrical signal from the first pin.

16. The battery system of claim 15, wherein, responsive to determining that the electrical signal from the first pin is not the high logic level and the electrical signal from the second pin is not the low logic level signal, the subpack microprocessor is configured to generate a notification indicating that the primary positive contactor is welded.

17. A method of monitoring a state of a battery system, wherein the battery system comprises:
a battery unit;
a positive contactor having:
a primary positive contactor electrically connected to a positive terminal of the battery unit and configured to move between a first state and a second state; and
an auxiliary positive contactor comprising a common (COM) pin, a first pin, and a second pin, wherein the COM pin is configured to be electrically connected to the first pin when the primary positive contactor is in the first state, and the COM pin is configured to be electrically connected to the second pin when the primary positive contactor is in the second state;
a negative contactor electrically connected to a negative terminal of the battery unit;
a microprocessor configured to control the positive contactor and the negative contactor;
a COM control circuit configured to provide an electrical signal to the COM pin;
an NC sensing circuit configured to monitor an electrical signal from the first pin and transmit first information about the electrical signal from the first pin to the microprocessor;
an NO sensing circuit configured to monitor an electrical signal from the second pin and transmit second information about the electrical signal from the second pin to the microprocessor,
wherein the method comprises:
determining, by the microprocessor, whether the battery system is in an abnormal state based on the first information about the electrical signal from the first pin and the second information about the electrical signal from the second pin.

18. The method of claim 17, comprising:
transmitting, by the microprocessor, a command to the COM control circuit to provide a high logic level signal to the COM pin;
transmitting, by the microprocessor, a command to move the primary positive contactor to the first state;
receiving, by the microprocessor from the NC sensing circuit, the first information about the electrical signal from the first pin;
receiving, by the microprocessor from the NO sensing circuit, the second information about the electrical signal from the second pin;
determining, by the microprocessor, whether the electrical signal from the first pin is a high logic level signal based on the first information about the electrical signal from the first pin; and
determining, by the microprocessor, whether the electrical signal from the second pin is a low logic level signal based on the second information about the electrical signal from the first pin.

19. The method of claim 18, comprising, responsive to determining that the electrical signal from the first pin is not the high logic level signal or the electrical signal from the second pin is not the low logic level signal:
transmitting, by the microprocessor, a command to the COM control circuit to provide the low logic level signal to the COM pin;
receiving, by the microprocessor from the NC sensing circuit, the first information about the electrical signal from the first pin;
determining, by the microprocessor, whether the electrical signal from the first pin is the low logic level signal based on the first information about the electrical signal from the first pin; and
responsive to determining that the electrical signal from the first pin is the low logic level signal, transmitting, by the microprocessor, a command to the COM control circuit to provide the high logic level signal to the COM pin.

20. The method of claim 19, comprising, subsequent to transmitting the command to the COM control circuit to provide the high logic level signal to the COM pin:
receiving, by the microprocessor from the NC sensing circuit, the first information about the electrical signal from the first pin;
receiving, by the microprocessor from the NO sensing circuit, the second information about the electrical signal from the second pin;
determining, by the microprocessor, whether the electrical signal from the first pin is the high logic level signal based on the first information about the electrical signal from the first pin;
determining, by the microprocessor, whether the electrical signal from the second pin is the low logic level signal based on the second information about the electrical signal from the first pin; and
responsive to determining that the electrical signal from the first pin is not the high logic level and the electrical signal from the second pin is not the low logic level signal, generating, by the microprocessor, a notification indicating that the primary positive contactor is welded.
